(19) United States
(12) Patent Application Publication
(10) Pub. No.: US 2017/0069794 A1
(43) Pub. Date: Mar. 9, 2017

(54) SEMICONDUCTOR LIGHT EMITTING DEVICE AND METHOD OF MANUFACTURING SAME

(71) Applicant: Ki Seok KIM, Hwaseong-si (KR)

(72) Inventor: Ki Seok KIM, Hwaseong-si (KR)

(21) Appl. No.: 15/257,340

(22) Filed: Sep. 6, 2016

(30) Foreign Application Priority Data
Sep. 3, 2015 (KR) 10-2015-0124912

(51) Int. Cl. H01L 33/38; H01L 33/12; H01L 33/20; H01L 33/32; H01L 33/42; H01L 33/46; H01L 33/62; H01L 33/00; F21V 23/02; F21K 9/235; F21V 29/77; F21V 23/00; F21K 9/238; F21V 7/00; F21V 23/04; H01L 33/06

(52) U.S. Cl. CPC H01L 33/38; H01L 33/06; H01L 33/12; H01L 33/20; H01L 33/32; H01L 33/42; H01L 33/46; H01L 33/62; H01L 33/007; F21V 23/02; F21K 9/235; F21V 29/77; F21V 23/003; F21K 9/238; F21V 7/00; F21V 23/045; H01L 2933/0016; H01L 2933/0025; H01L 2933/0066; F21Y 2115/10

(57) ABSTRACT

An LED includes a semiconductor stack including a first conductive semiconductor layer, a second conductive semiconductor layer, an active layer disposed between the first and second conductive semiconductor layers, and trenches formed passing through the second conductive semiconductor layer and the active layer to expose portions of the first conductive semiconductor layer disposed underneath the active layer; a first electrode finger disposed along the trenches and electrically connected to the portions of the first conductive semiconductor layer exposed within the trenches; an insulating layer on which the first electrode finger is positioned and which is disposed on the second conductive semiconductor layer and internal side walls of the trenches; and a second electrode finger electrically connected to the second conductive semiconductor layer.

### CROSS-REFERENCE TO RELATED APPLICATION

This application claims priority from Korean Patent Application No. 10-2015-0124912, filed on Sep. 3, 2015, in the Korean Intellectual Property Office, the disclosure of which is incorporated herein by reference in its entirety.

### BACKGROUND

Apparatuses and methods consistent with exemplary embodiments relate to a semiconductor light emitting device (LED).

LEDs generate light within certain wavelength bands through the recombination of electrons and holes. Since LEDs have a longer effective lifespan, low power consumption, excellent initial driving characteristics, and the like, as compared to filament-based light sources, demand for LEDs continues to increase. In particular, group III nitride semiconductors able to emit short-wavelength blue light have drawn attention.

Recently, improvements in the light emitting efficiency of LEDs have been actively researched. In particular, various kinds of electrode structures have been developed to improve the light emitting efficiency and optical power of LEDs.

### SUMMARY

Exemplary embodiments address at least the above problems and/or disadvantages and other disadvantages not described above. Also, the exemplary embodiments are not required to overcome the disadvantages described above, and may not overcome any of the problems described above.

One or more exemplary embodiments may provide an LED having a novel electrode structure which may prevent light emitting efficiency from deteriorating and improve optical power, and a method of manufacturing the same.

According to an aspect of an exemplary embodiment, there is provided an LED, which includes a semiconductor stack including a first conductive semiconductor layer, a second conductive semiconductor layer, an active layer disposed between the first and second conductive semiconductor layers, and a plurality of trenches passing through the second conductive semiconductor layer and the active layer to portions of the first conductive semiconductor layer; a first electrode finger disposed along the plurality of trenches and electrically connected to the portions of the first conductive semiconductor layer within the trenches; an insulating layer disposed on portions of the second conductive semiconductor layer and internal side walls of the trenches on which the first electrode finger is positioned; and a second electrode finger electrically connected to the second conductive semiconductor layer.

The LED may further include a current distribution layer disposed on the second conductive semiconductor layer, in which the second electrode finger may be disposed on the current distribution layer.

The current distribution layer may be disposed on an upper surface of the second conductive semiconductor layer except for a portion in which the first electrode finger is disposed.

The current distribution layer may include a transparent electrode layer. For example, the current distribution layer may contain at least one selected from indium tin oxide (ITO), zinc-doped ITO (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In₄Sn₃O₁₂, and zinc magnesium oxide (Zn₍₁₋ₓ₎MgₓO, 0≦x≦1).

The first electrode finger and portions of the insulating layer disposed below the first electrode finger may form an omni-directional reflector (ODR).

At least a portion of the insulating layer may include a distributed Bragg reflector (DBR) multilayer film.

At least one of intervals between each of the plurality of trenches may be different from an interval between other trenches.

A contact area between the first electrode finger and the first conductive semiconductor layer in at least one of the plurality of trenches may be different from a contact area in the other trench.

The LED may further include a first electrode pad and a second electrode pad respectively connected to the first electrode finger and the second electrode finger.

The first electrode pad may be disposed on a portion of the insulating layer positioned on the second conductive semiconductor layer, and the second electrode pad may be disposed on the second conductive semiconductor layer.

At least a portion of the plurality of trenches may be arranged at an interval that is increased farther away from the first electrode pad. Alternatively, the contact area between the first electrode finger and the first conductive semiconductor layer in the at least one of the plurality of trenches may be decreased when the at least one trench is farther away from the first electrode pad.

The at least one of the plurality of trenches may be arranged at an interval that is decreased farther away from the first electrode pad. Alternatively, the contact area between the first electrode finger and the first conductive semiconductor layer in the at least one trench may be increased when the at least one trench is farther away from the first electrode pad.

According to an aspect of an exemplary embodiment, there is provided an LED, which includes a semiconductor stack including a first conductive semiconductor layer, a second conductive semiconductor layer, an active layer disposed between the first and second conductive semiconductor layers, and a plurality of first trenches and at least one second trench passing through the second conductive semiconductor layer and the active layer to portions of the first conductive semiconductor layer; a first electrode finger disposed along the plurality of first trenches and connected to the portions of the first conductive semiconductor layer within the first trenches; an insulating layer disposed on the second conductive semiconductor layer and internal side walls of the first trenches where the first electrode finger is positioned, and an internal surface of the at least one second trench; and a second electrode finger disposed on the insulating layer within the at least one second trench and electrically connected to the second conductive semiconductor layer.

The LED may further include a current distribution layer disposed on the second conductive semiconductor layer and electrically connected to the second electrode finger, in which the current distribution layer may extend into the at least one second trench along an upper surface of the insulating layer, and the second electrode finger may be disposed on a portion of the current distribution layer positioned within the at least one second trench.

The first trenches and the at least one second trench may have substantially the same depth.

The at least one second trench may include a plurality of trenches, and the second electrode finger may be disposed along the plurality of trenches.

The LED may further include a first electrode pad and a second electrode pad respectively connected to the first electrode finger and the second electrode finger, wherein the insulating layer may have a portion extending between the second electrode pad and the second conductive semiconductor layer.

According to an aspect of an exemplary embodiment, there is provided a method of manufacturing an LED, the method including: forming a semiconductor stack by sequentially growing a first conductive semiconductor layer, an active layer, and a second conductive semiconductor layer on a substrate; forming a plurality of trenches in the semiconductor stack, the plurality of trenches passing through the second conductive semiconductor layer and the active layer to portions of the first conductive semiconductor layer; forming an insulating layer along the plurality of trenches to expose each of the portions of the first conductive semiconductor layer in each of the plurality of trenches; forming a first electrode finger along the plurality of trenches to be electrically connected to the exposed portions of the first conductive semiconductor layer; and forming a second electrode finger to be electrically connected to the second conductive semiconductor layer.

### BRIEF DESCRIPTION OF DRAWINGS

The above and/or other aspects will become more apparent by describing certain exemplary embodiments with reference to the accompanying drawings, in which:

FIG. 1 is a schematic plan view of an LED according to an exemplary embodiment;

FIG. 2 is a schematic cross-sectional view taken along line X-X′ of the LED illustrated in FIG. 1;

FIG. 3 is a schematic cross-sectional view taken along line Y-Y′ of the LED illustrated in FIG. 1;

FIGS. 4A, 4B, 4C, and 4D are cross-sectional views of a process of manufacturing an LED according to an exemplary embodiment;

FIG. 5 is a schematic plan view of an LED according to an exemplary embodiment;

FIG. 6 is a schematic cross-sectional view taken along line I-I′ of the LED illustrated in FIG. 5;

FIG. 7 is a schematic plan view of an LED according to an exemplary embodiment;

FIG. 8 is a schematic cross-sectional view taken along line X1-X1′ of the LED illustrated in FIG. 7;

FIG. 9 is a schematic cross-sectional view taken along line X2-X2′ of the LED illustrated in FIG. 7;

FIG. 10 is a schematic cross-sectional view taken along line Y-Y′ of the LED illustrated in FIG. 7;

FIG. 11 is a schematic plan view of an LED according to an exemplary embodiment;

FIG. 12 is a schematic cross-sectional view taken along line X3-X3′ of the LED illustrated in FIG. 11;

FIG. 13 is a side cross-sectional view of an LED package employing the LED according to an exemplary embodiment;

FIG. 14 is a side cross-sectional view of an LED package employing the LED according to an exemplary embodiment;

FIG. 15 is a cross-sectional view of an edge-type backlight unit employing an LED according to an exemplary embodiment;

FIG. 16 is a cross-sectional view of a direct-type backlight unit employing an LED according to an exemplary embodiment;

FIG. 17 is an exploded perspective view of a display device employing an LED according to an exemplary embodiment; and

FIG. 18 is an exploded perspective view of a lighting device including an LED according to an exemplary embodiment.

### DETAILED DESCRIPTION

Certain exemplary embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the exemplary embodiments. However, it is apparent that the exemplary embodiments can be practiced without those specifically defined matters. Also, well-known functions or constructions are not described in detail since they would obscure the description with unnecessary detail.

Throughout the specification, it will be understood that when an element, such as a layer, region or substrate, is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting of the present disclosure. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

In the drawings, for example, due to manufacturing techniques and/or tolerances, modifications of the shape shown may be estimated. Thus, exemplary embodiments should not be construed as being limited to the particular shapes of regions shown herein, for example, to include a change in shape results in manufacturing. The following embodiments may also be constituted as one or a combination thereof.

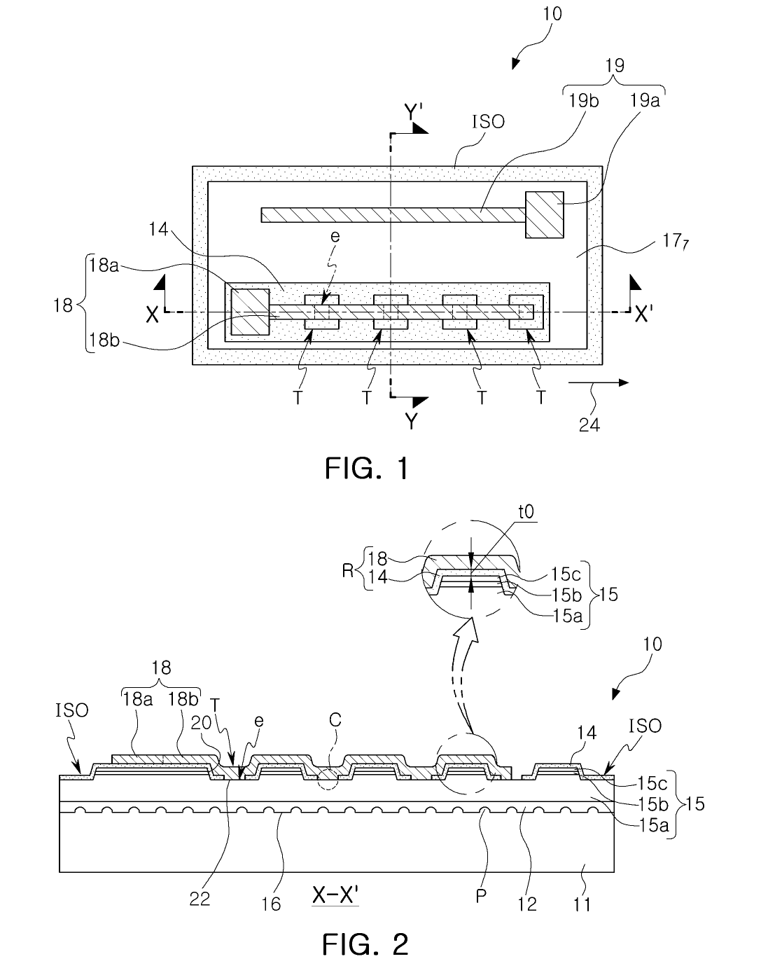

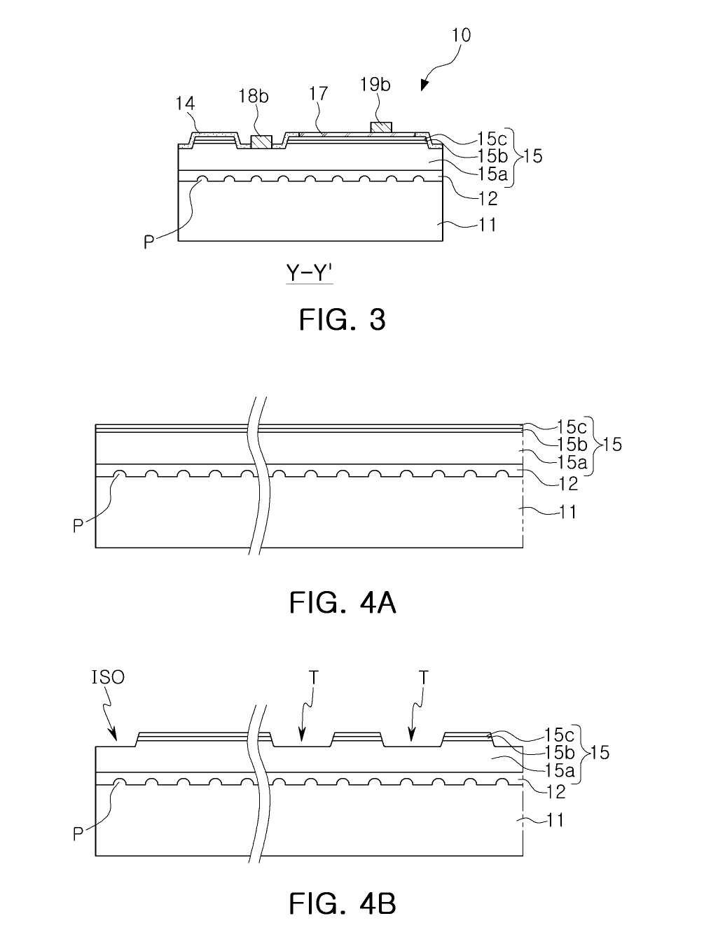

FIG. 1 is a schematic plan view of an LED according to an exemplary embodiment. FIGS. 2 and 3 are schematic cross-sectional views respectively taken along lines X-X′ and Y-Y′ of the LED illustrated in FIG. 1.

Referring to FIGS. 1 through 3, an LED 10 according to an exemplary embodiment may include a substrate 11 and a semiconductor stack 15 disposed on the substrate 11.

The semiconductor stack 15 may include a first conductive semiconductor layer 15a, an active layer 15b, and a second conductive semiconductor layer 15c. A buffer layer 12 may be provided between the substrate 11 and the first conductive semiconductor layer 15a.

The substrate 11 may be an insulating, conductive, and/or semiconductor substrate. For example, the substrate 11 may include at least one of sapphire, SiC, Si, MgAl₂O₄, MgO, LiAlO₂, LiGaO₂, or GaN. An uneven portion P may be formed on an upper surface 16 of the substrate 11. The uneven portion P may increase light extraction efficiency and improve quality of a single crystal being grown. The uneven portion P may be a hemispherical projection as shown in FIG. 2 of an exemplary embodiment, but is not limited thereto, and may be a non-flat structure having various other shapes and irregularities.

The buffer layer 12 may be InₓAl_{y}Ga_{1-x-y}N (0≦x≦1, 0≦y≦1). For example, the buffer layer 12 may include at least one of AlN, AlGaN, InGaN, GaN, or InAlGaN. For example, the buffer layer 12 may be formed by combining a plurality of layers or gradually changing compositions thereof.

The first conductive semiconductor layer 15a may be an n-type nitride semiconductor layer having a composition of AlₓIn_{y}Ga_{1-x-y}N (0≦x≦1, 0≦y≦1, 0≦x+y≦1), and an n-type impurity may be Si. For example, the first conductive semiconductor layer 15a may be an n-type GaN. The second conductive semiconductor layer 15c may be a p-type nitride semiconductor layer having a composition of AlₓIn_{y}Ga_{1-x-y}N, and a p-type impurity may be Mg. For example, the second conductive semiconductor layer 15c may be a p-type AlGaN/GaN. The active layer 15b may be a multiple quantum well (MQW) structure in which quantum well layers and quantum barrier layers are alternately stacked with each other. For example, in a case in which a nitride semiconductor is used, the active layer 15b may be a GaN/InGaN MQW structure.

A first electrode 18, e.g., an n-type electrode, and a second electrode 19, e.g., a p-type electrode may include a first electrode pad 18a and a second electrode pad 19a, and a plurality of first electrode fingers 18b and a plurality of second electrode fingers 19b extending therefrom, respectively. In an exemplary embodiment, the first electrode pad 18a and the second electrode pad 19a may be disposed in the opposing corners of the LED 10, as seen in the plan view, but this is not limiting. As a non-limiting example, the plurality of first and second electrode fingers 18b and 19b may be arranged substantially parallel to each other, to extend from the respective first and second electrode pads 18a and 19a. In an exemplary embodiment of FIG. 1, only one of each of the first and second electrode pads 18a and 19a are shown. However, in an exemplary embodiment, at least one of the first and second electrode pads 18a and 19a may include a plurality of pads.

The semiconductor stack 15 may include a plurality of trenches T. In an exemplary embodiment of FIG. 1, four trenches T are shown, but this is not limiting and more or fewer trenches may be implemented. The trenches T may extend through the second conductive semiconductor layer 15c and the active layer 15b to portions of the first conductive semiconductor layer 15a.

The plurality of trenches T may be arranged in portions in which the first electrode fingers 18b are formed. For example, the plurality of trenches T may be arranged in a longitudinal direction 24 in which the first electrode fingers 18b extend from the first electrode pad 18a.

An insulating layer 14 may be formed on an upper surface of the semiconductor stack 15. As illustrated in FIG. 2, the insulating layer 14 may be provided on portions of the second conductive semiconductor layer 15c and internal side walls 20 of the trenches T that are formed by the semiconductor stack, underneath the first electrode fingers 18b are positioned. The insulating layer 14 may guarantee selective contact to the first electrode fingers 18b disposed along the trenches T.

In particular, as illustrated in FIG. 2, the insulating layer 14 may allow portions e of the first conductive semiconductor layer 15a to be exposed in the openings formed at bottom surfaces 22 of the trenches T that are formed by an upper surface of the first conductive semiconductor layer 15a, while the portions of the second conductive semiconductor layer 15c and the internal side walls of the trenches T on which the first electrode fingers 18b are positioned may be insulated.

Therefore, even when the first electrode fingers 18b are disposed in a direction in which the plurality of trenches T are arranged, the first electrode fingers 18b may have portions C electrically connected to the portions of the first conductive semiconductor layer 15a on the bottom surfaces of the trenches T, but may be electrically insulated from a mesa region (for example, the active layer 15b and the second conductive semiconductor layer 15c) positioned between the trenches T.

As such, an effective light emission region in accordance with the formation of the first electrode fingers 18b may be reduced by forming the plurality of trenches without etching all portions on which the first electrode fingers 18b are to be formed. As a result, light emission efficiency of the LED 10 may be increased. Meanwhile, effects of a micro LED (an increase in light efficiency) may be expected by properly adjusting an interval between the trenches T, that is, the mesa region to a micro size and allowing the mesa region to function as a micro LED cell.

In such a structure, as illustrated in FIG. 2, portions of the insulating layer 14 positioned on the internal side walls of the trenches T and a periphery thereof and the first electrode fingers 18b positioned on the portions of the insulating layer 14 may be provided as an omni-directional reflector (ODR) R formed by a combination of a low refractive index layer (for example, insulating layer 14) and a reflective metal. The reflective metal alone might not allow reflectivity having a certain threshold value or more to be obtained due to an extinction coefficient of characteristics of the reflective metal itself (for example, threshold value of reflectivity; 86% of Ag, 92% of Al). The ODR introduced in an exemplary embodiment may have high reflectivity for the overall orientation angle with a structure in which a relatively low refractive index layer and a reflective metal are stacked, and may be expected to provide high light extraction efficiency. Without being limited thereto, for example, the reflective metal for the first electrode fingers 18b or a lower additional layer thereof may be used with a material such as Ag, Al, or Rh. The insulating layer 14 may be used with a material such as SiO₂, Si₃N₄, HfO₂, SiON, TiO₂, Ta₂O₃, or SnO₂, and may have a proper thickness t0 depending on a refractive index or the like of the insulating layer 14, thereby providing a desired ODR structure.

In an exemplary embodiment, the first electrode pad 18a may be disposed on the second conductive semiconductor layer 15c along with the second electrode pad 19a. The first electrode pad 18a may include the insulating layer 14 provided therebelow to be insulated from the second conductive semiconductor layer 15c. As such, the effective light emission region may be additionally reduced by not applying etching for exposing the first conductive semiconductor layer 15a to a region in which the first electrode pad 18a is formed. For example, the insulating layer 14 may be formed on a lower portion of the second electrode pad 19a to be used as a current blocking layer. Such a current blocking layer may allow an electrical current to be distributed more effectively through the second electrode fingers 19b.

A current distribution layer 17 may be disposed on substantially entire the second conductive semiconductor layer 15c. The current distribution layer 17 may come in ohmic contact with the second conductive semiconductor layer 15c, and may uniformly distribute an electrical current delivered through the second electrode 19 to the second conductive semiconductor layer 15c. The current distribution layer 17 may be formed over an entire region of an upper surface of the second conductive semiconductor layer 15c, for example with an exception of an area corresponding to an area where at least a portion of the first conductive electrode is formed. For example, in a case in which the insulating layer 14 is disposed on the second conductive semiconductor layer 15c, the current distribution layer 17 may be formed before the formation of the insulating layer 14, and thus the current distribution layer 17 may be positioned below the insulating layer 14.

The current distribution layer 17 may be a transparent conductive oxide. For example, the current distribution layer 17 may be a light transmitting conductive oxide such as ITO, ZITO, ZIO, GIO, ZTO, FTO, AZO, GZO, In₄Sn₃O₁₂, or Zn₍₁₋ₓ₎MgₓO (0≦x≦1).

In an exemplary embodiment, the current distribution layer 17 disposed on the second conductive semiconductor layer 15c is provided as an example, and the current distribution layer 17 may be partially or entirely omitted. The insulating layer 14 may be provided as a passivation layer of the LED 10, in an exemplary embodiment. For example, the insulating layer 14 may include an isolation region around the LED 10 to be provided on a surface of the semiconductor stack 15 except for a region in which the current distribution layer 17 is to be formed.

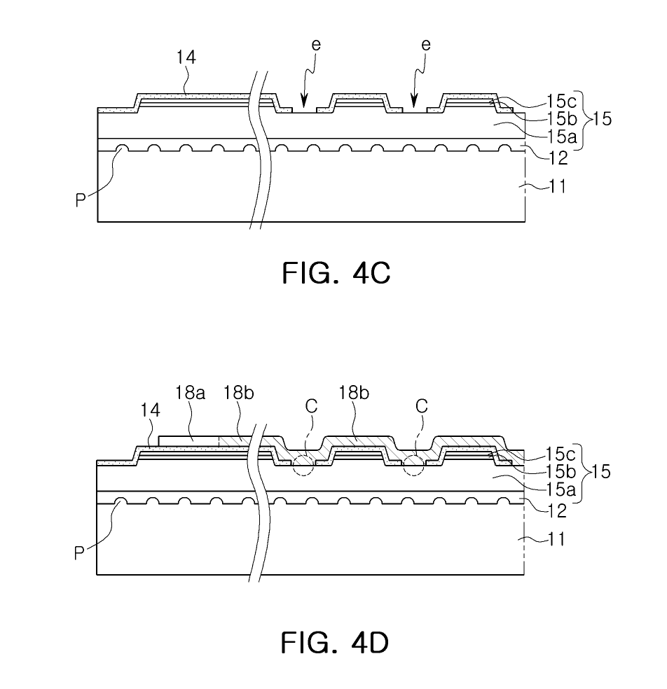

FIGS. 4A through 4D are cross-sectional views taken along line X-X′ of the LED illustrated in FIG. 1, respectively, as cross-sectional views of operations illustrating a process of manufacturing an LED illustrated in FIG. 1.

As illustrated in FIG. 4A, the buffer layer 12 may be formed on the substrate 11, and the semiconductor stack 15 for an LED may be formed on the buffer layer 12.

The semiconductor stack 15 may include the first conductive semiconductor layer 15a, the active layer 15b, and the second conductive semiconductor layer 15c, and may be the nitride semiconductor described above. The semiconductor stack 15 may be grown on the substrate 11 using processes such as metalorganic chemical vapor deposition (MOCVD), molecular beam epitaxy (MBE), and hydride vapor phase epitaxy (HVPE).

Subsequently, as illustrated in FIG. 4B, the trenches T may be formed in the semiconductor stack 15 so that portions e of the first conductive semiconductor layer 15a may be exposed.

This may be implemented by an etching process of partially removing the second conductive semiconductor layer 15c and the active layer 15b. In the exemplary trench forming process, an isolation ISO etching process of dividing the semiconductor stack 15 into device units may also be performed. The isolation ISO region and the trenches T may have substantially the same depth. The portions of the first conductive semiconductor layer 15a exposed by the trenches T may be provided to be connected to the first electrode fingers 18b.

Next, as illustrated in FIG. 4C, the insulating layer 14 may be formed on the semiconductor stack 15 in which the trenches T are formed.

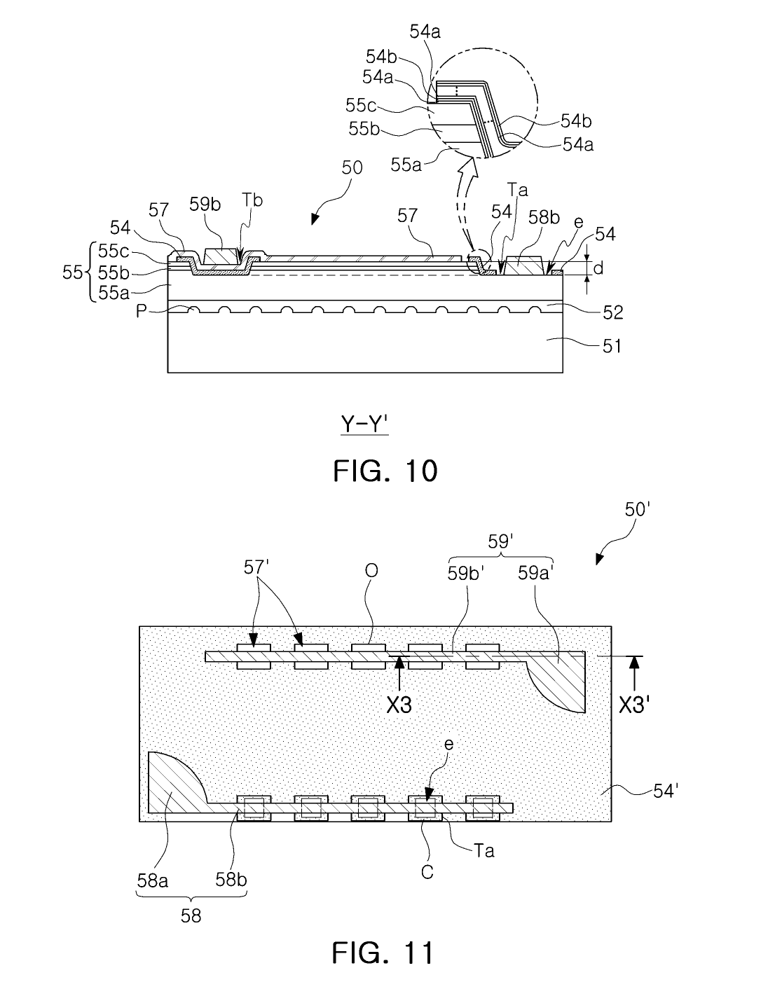

The insulating layer 14 formed in this process may be obtained by being deposited on the entire region of surfaces in which the trenches T are formed, and then selectively removing portions of the insulating layer 14. The insulating layer 14 may cover the internal side walls of the trenches T, the periphery of the trenches T, and upper portions of the second conductive semiconductor layer 15c between the trenches T. The insulating layer 14 may have openings e in the bottom surfaces of the trenches T to allow the portions of the first conductive semiconductor layer 15a to be exposed. For example, the insulating layer 14 may be SiO₂, Si₃N₄, HfO₂, SiON, TiO₂, Ta₂O₃, or SnO₂. As described above, the insulating layer 14 may be provided as the ODR structure along with the first electrode 18 to be formed in the described process. The insulating layer 14 may be a DBR multilayer film in which dielectric films having different refractive indexes are alternately stacked. As such, employing the insulating layer 14 as the ODR structure or a DBR multilayer film structure may further increase light extraction efficiency (refer to FIG. 10).

Subsequently, although not shown in FIGS. 4A to 4C, the current distribution layer 17 may be formed on the upper surface of the second conductive semiconductor layer 15c. The current distribution layer 17 may come in ohmic contact with the second conductive semiconductor layer 15c, and may uniformly distribute an electrical current delivered through the second electrode 19 to the second conductive semiconductor layer 15c. Such a conductive oxide may be subject to an additional thermal treatment process (for example, 500° C. or more) after a deposition process to obtain a desired electrical/optical characteristic.

Next, as illustrated in FIG. 4D, the first electrode 18 may be formed along the trenches T.

In this process, the first electrode pad 18a may be formed on a portion of the insulating layer 14 positioned on the second conductive semiconductor layer 15c, and the first electrode fingers 18b may be formed along the plurality of trenches T to be connected to the exposed portions e of the first conductive semiconductor layer 15a. The first electrode fingers 18b may be insulated from undesired portions by the insulating layer 14. Although not shown in FIG. 4D, the second electrode 19 illustrated in FIGS. 1 and 3 may also be formed together with the first electrode or sequentially.

For example, the first and second electrodes 18 and 19 may contain materials, such as Ag, Ni, Al, Rh, Pd, Ir, Ru, Mg, Zn, Pt, and Au, and may be employed as a structure having a single layer or two or more layers. Although not limited thereto, the first and second electrodes 18 and 19 may be formed by substantially the same electrode forming process and of substantially the same electrode material.

In addition, in the present electrode forming process, the first and second electrode fingers 18b and 19b may be formed along with the first and second electrode pads 18a and 19a, and may be formed of substantially the same electrode material. For example, the first and second electrode pads 18a and 19a may have additional bonding metals such as Au, Sn, and Au/Sn, using a separate process.

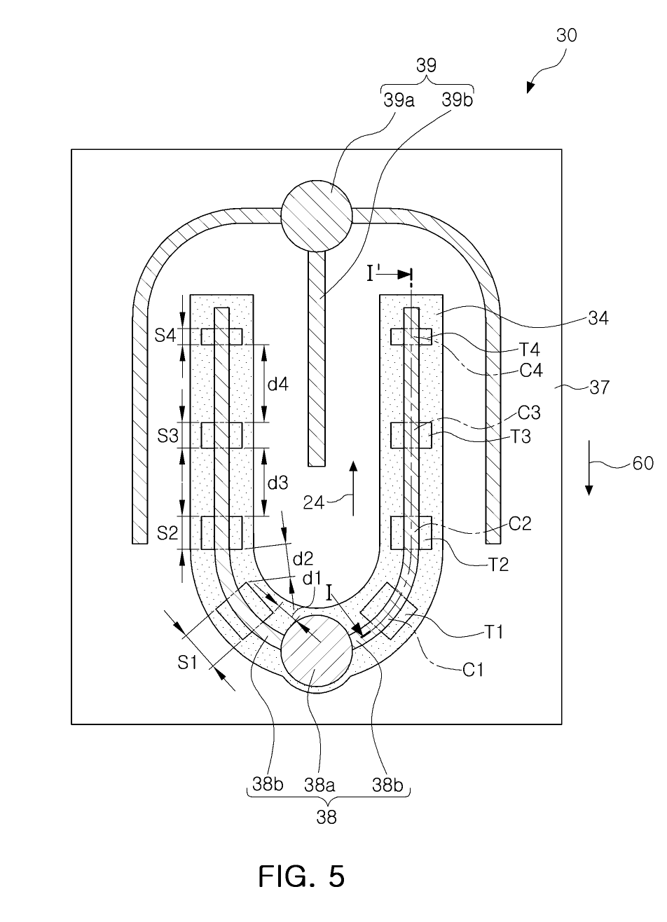

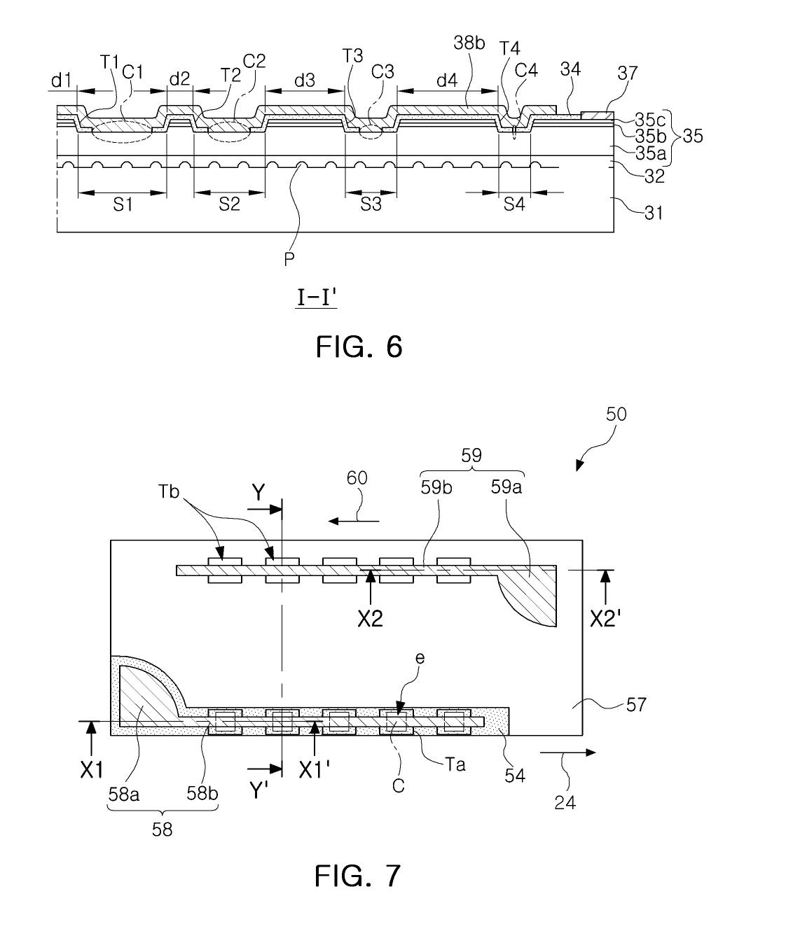

FIG. 5 is a schematic plan view of an LED according to an exemplary embodiment. FIG. 6 is a schematic cross-sectional view taken along line I-I′ of the LED illustrated in FIG. 1.

Referring to FIGS. 5 and 6, an LED 30 according to an exemplary embodiment may include a substrate 31 and a semiconductor stack 35 disposed on the substrate 31.

The semiconductor stack 35 may include a first conductive semiconductor layer 35a, an active layer 35b, and a second conductive semiconductor layer 35c. A buffer layer 32 may be disposed between the substrate 31 and the first conductive semiconductor layer 35a. Unless particularly otherwise noted, the components adapted in this exemplary embodiment are identical or similar to the components described above with reference to exemplary embodiments.

A first electrode 38 and a second electrode 39 may include a first electrode pad 38a and a second electrode pad 39a, and a plurality of first electrode fingers 38b and a plurality of second electrode fingers 39b extending therefrom, respectively, and arranged to cross each other. As a non-limiting example, the first electrode pad 38a and the second electrode pad 39a may be arranged so as to oppose one another. The first electrode fingers 38b may extend from both sides of the first electrode pad 38a and may be curved. For example, one second electrode finger 39b may extend from the second electrode pad 39a toward the first electrode pad 38a so that it becomes positioned inside an area formed by the first electrode fingers 38b, and two second electrode fingers 39b may extend on an outside of the first electrode fingers 38b and may be curved, but this is not limiting. The second electrode 39 may provide an electrical current to the second conductive semiconductor layer 35c through a current distribution layer 37. The current distribution layer 37 may be a transparent conductive oxide. For example, the current distribution layer 37 may be a light transmitting conductive oxide such as ITO, ZITO, ZIO, GIO, ZTO, FTO, AZO, GZO, In₄Sn₃O₁₂, or Zn₍₁₋ₓ₎MgₓO (0≦x≦1).

The first electrode 38 may be connected to portions of the first conductive semiconductor layer 35a exposed by a plurality of trenches T1, T2, T3, and T4. As illustrated in FIGS. 5 and 6, the semiconductor stack 35 may include an arrangement of the plurality of trenches T1 to T4. As illustrated in FIG. 6, the trenches T1 to T4 may pass through the second conductive semiconductor layer 35c and the active layer 35b to the portions of the first conductive semiconductor layer 35a.

In an exemplary embodiment, the plurality of trenches T1 to T4 may be provided in two rows for two first electrode fingers 38b. Each of the rows including the trenches T1 to T4 may be formed in a direction in which the first electrode fingers 38b extend from the first electrode pad 38a. For example, the trenches T1 to T4 disposed in the rows may face each other, respectively. An insulating layer 34 may be provided on portions of the second conductive semiconductor layer 35c and internal side walls of the trenches T1 to T4 where the first electrode fingers 38b are positioned. As illustrated in FIG. 6, the insulating layer 34 may allow the portions of the first conductive semiconductor layer 35a to be exposed by not being disposed, e.g., being etched, etc., on the bottom surfaces of the trenches T1 to T4, while the portions of the second conductive semiconductor layer 35c and the internal side walls of the trenches T1 to T4 where the first electrode fingers 38b are positioned may be insulated from each other.

The first electrode fingers 38b may be electrically connected to the exposed portions of the first conductive semiconductor layer 35a on the bottom surfaces of the trenches T1 to T4, but may be electrically insulated from a mesa region positioned between the trenches T1 to T4.

As such, use of the trenches T1 to T4 may allow an effective light emission region in accordance with the formation of the first electrode fingers 38b to be reduced. In addition, portions of the insulating layer 34 positioned on the internal side walls of the trenches T1 to T4 and a periphery thereof and the second electrode fingers 39b positioned on the portions of the insulating layer 34 may be provided as an ODR structure, thereby substantially increasing light extraction efficiency.

The arrangement of the plurality of trenches T1 to T4 and an area of contact portions C1 to C4 may be adjusted to contribute to reducing current crowding. Referring to FIG. 5, four trenches T1 to T4 may be arranged to have intervals that are increased as the distance of the trench positions from the first electrode pad 38a increases (d1<d2<d3<d4). Such an arrangement may attenuate current supply in a surrounding region of the first electrode pad 38a, and may strengthen current supply in the surrounding region of the second electrode pad 39a. For a purpose similar thereto, the contact portions C1 to C4 of the respective trenches T1 to T4 may have areas that are decreased farther away from the first electrode pad 38a (C1>C2>C3>C4), respectively. The trenches T1 to T4 may be of different sizes in order to vary areas of the contact portions C1 to C4 between the first electrode fingers 38b and the first conductive semiconductor layer 35a. For example, the trenches T1 to T4 may be of large sizes (S1>S2>S3>S4) in order to increase the areas of the contact portions C1 to C4 (C1>C2>C3>C4).

The arrangement of the plurality of trenches T1 to T4 and the area of the contact portions C1 to C4 are shown and described as an example, as a measure to ease current crowding in a surrounding region of the second electrode pad 39a; however, such arrangement is not limiting.

For example, in a case of an arrangement of electrodes in which current crowding occurs in another region, other arrangements of the trenches T1 to T4 and/or adjustment of the areas of the contact portions C1 to C4 may be applied. For example, in an electrode arrangement similar to an exemplary embodiment, when current crowding occurs in a periphery of the first electrode pad 38a, the four trenches T1 to T4 may be arranged to have intervals that are decreased farther away from the first electrode pad 38a, respectively, or may have areas with an increased area size, respectively, as the contact portions C1 to C4 of the respective trenches T1 to T4 are farther away from the first electrode pad 38a.

In an exemplary embodiment, the intervals between each of the trenches T1 to T4 or the areas of the contact portions C1 to C4 are shown as being only gradually changed as an example. As another example, only intervals between each of portions of the trenches T1 to T4 or only areas of portions of the contact portions C1 to C4 may be adjusted. For example, at least one of the intervals between each of the plurality of trenches T1 to T4 may be determined to be different from intervals between each of other trenches, or areas of contact portions between the first electrode fingers 38b on at least one of the plurality of trenches T1 to T4 and the first conductive semiconductor layer 35a may be determined to be different from areas of contact portions between each of other trenches.

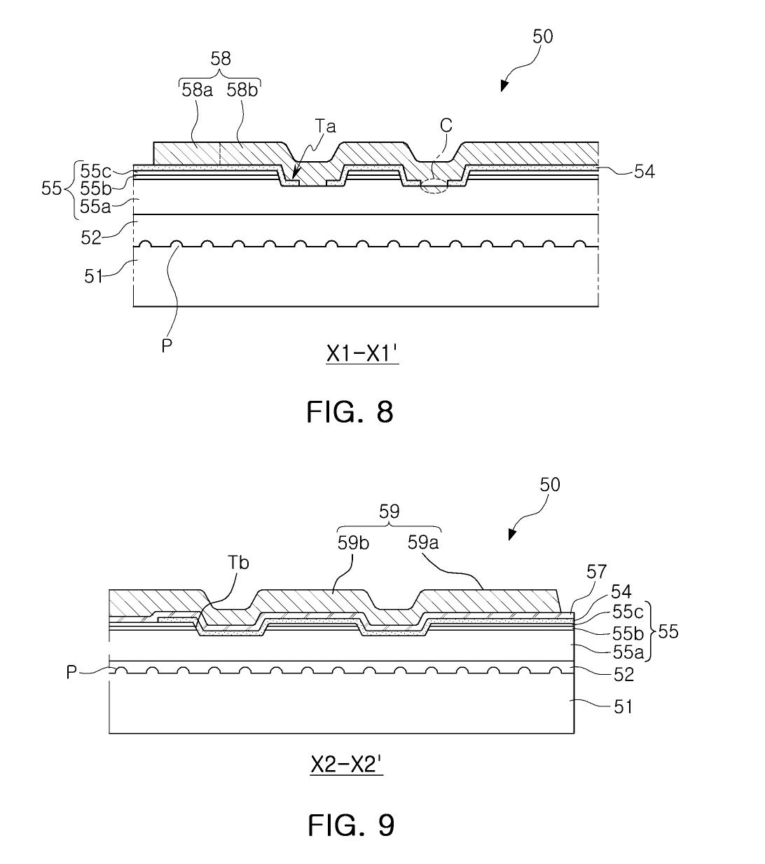

FIG. 7 is a schematic plan view of an LED according to an exemplary embodiment. FIGS. 8 through 10 are schematic cross-sectional views respectively taken along lines X1-X1′, X2-X2′, and Y-Y′ of the LED illustrated in FIG. 7.

Referring to FIGS. 7 and 8, an LED 50 according to an exemplary embodiment may include a substrate 51 and a semiconductor stack 55 disposed on the substrate 51.

The semiconductor stack 55 may include a first conductive semiconductor layer 55a, an active layer 55b, and a second conductive semiconductor layer 55c as illustrated in FIG. 8. A buffer layer 52 may be provided between the substrate 51 and the first conductive semiconductor layer 55a. Unless specifically otherwise noted, the components adapted in this exemplary embodiment are identical or similar to the components described above with reference to various exemplary embodiments.

A first electrode 58 and a second electrode 59 may include a first electrode pad 58a and a second electrode pad 59a, and a first electrode finger 58b and a second electrode finger 59b extending therefrom, respectively. In an exemplary embodiment, the first and second electrode fingers 58b and 59b may extend from the first and second electrode pads 58a and 59a, respectively, and may be disposed proximate or adjacent to opposing sides of the LED, respectively.

The semiconductor stack 55 may include one or more first trenches Ta for the first electrode finger 58b and one or more second trenches Tb for the second electrode finger 59b. The first and second trenches Ta and Tb may pass through the second conductive semiconductor layer 55c and the active layer 55b to allow portions of the first conductive semiconductor layer 55a to be exposed, and may be arranged in longitudinal directions 24 and 60 of the first and second electrode fingers 58b and 59b, respectively. As illustrated in FIG. 10, the first and second trenches Ta and Tb may have substantially the same depth d, and, thus, may be formed by an identical process.

The first electrode finger 58b may be formed in a direction in which the first trenches Ta are arranged. As illustrated in FIG. 8, an insulating layer 54 may be provided on portions of the second conductive semiconductor layer 55c and internal side walls of the first trenches Ta where the first electrode finger 58b is positioned, and may allow the first electrode finger 58b to have portions C electrically connected to the portions of the first conductive semiconductor layer 55a on bottom surfaces of the first trenches Ta by having openings in at least portions e of the bottom surfaces of the first trenches Ta. Here, the first electrode fingers 38b may be electrically insulated from a surface of a mesa region positioned between the first trenches Ta.

An effective light emission region may be reduced by forming the plurality of first trenches Ta by not etching all regions in which the first electrode 58 is to be formed. An additional current distribution effect may be expected to be provided in a region in which an electrical current is concentrated by adjusting distance to each trench and/or between the trenches as described above (refer to FIG. 5). Disposing the insulating layer 58 below the first electrode 58 may allow a metal forming the first electrode 58 and the insulating layer 54 to be provided as an ODR structure, thereby substantially improving light extraction efficiency.

Alternatively, the insulating layer 54 may be a DBR multilayer film in which dielectric films having different refractive indexes are alternately stacked. As illustrated in FIG. 10, the insulating layer 54 may be a reflective structure in which a first insulating layer 54a and a second insulating layer 54b having different refractive indexes are alternately stacked.

Intervals between each of the first trenches Ta may be controlled to provide a light emission region therebetween to have a micro size, and light efficiency may be greatly increased with effects of a micro LED.

The second electrode finger 59b may be disposed along the second trenches Tb and an upper surface of the second conductive semiconductor layer 55c between the second trenches Tb. Thus, the second electrode finger 59b may have a curved shape as illustrated in FIG. 9. The insulating layer 54 may extend on internal surfaces of the second trenches Tb so that the first conductive semiconductor layer 55a as well as the second conductive semiconductor layer 55c and the active layer 55b are not exposed. Thus, even when the second electrode finger 59b is formed along the internal surfaces of the plurality of second trenches Tb, the second electrode finger 59b may be prevented from being undesirably connected to the first conductive semiconductor layer 55a and the active layer 55b.

In an exemplary embodiment, a current dispersion layer 57 may be formed on the upper surface of the second conductive semiconductor layer 55c and on the insulating layer 54 disposed on the internal side surfaces of the second trenches T2 that are formed by a the semiconductor stack and on the bottom surface of the second trenches that is formed by an upper surface of the first conductive semiconductor layer 55a. The second electrode finger 59b may be connected to the current dispersion layer 57 in the second trenches T2. In an exemplary embodiment, disposing the second electrode finger 59b along the plurality of second trenches T2 may allow the second electrode finger 59b to be disposed at a relatively low depth, as that of the bottom surface of the second trenches T2, thereby improving light extraction efficiency.

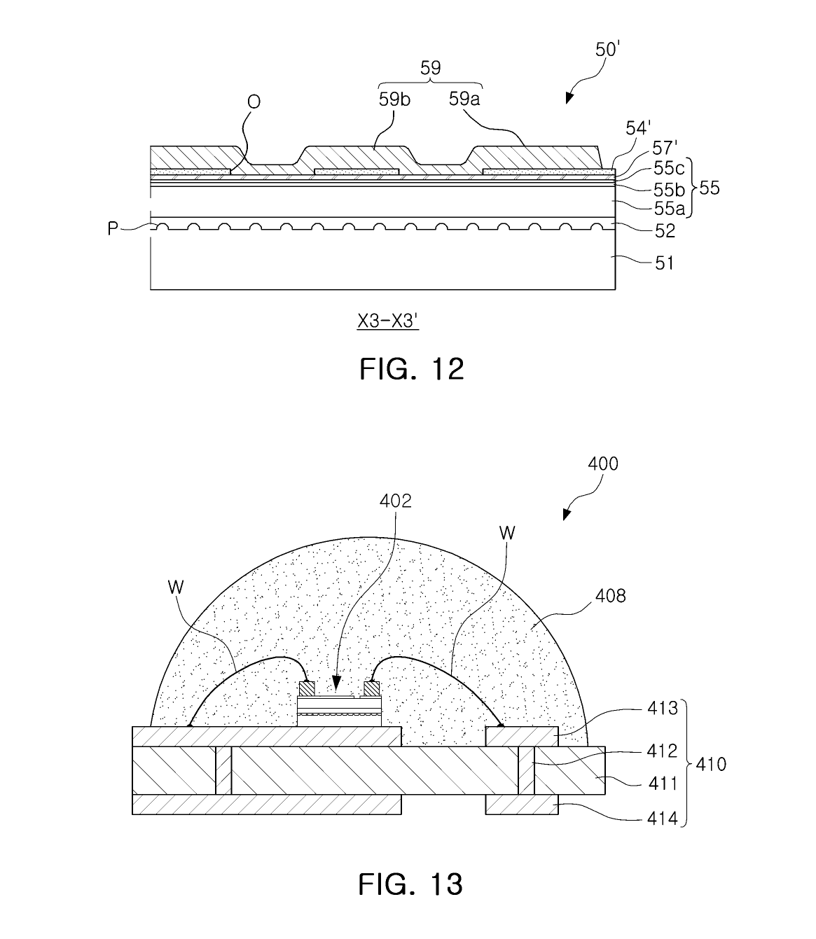

FIG. 11 is a schematic plan view of an LED according to an exemplary embodiment. FIG. 12 is a schematic cross-sectional view taken along line X3-X3′ of the LED illustrated in FIG. 11.

As illustrated in FIGS. 11 and 12, an LED 50′ may include a substrate 51 and a semiconductor stack 55 disposed on the substrate 51, similar to the LED 50 described above with reference to the exemplary embodiments. The semiconductor stack 55 may include a first conductive semiconductor layer 55a, an active layer 55b, and a second conductive semiconductor layer 55c. The substrate 51 and the semiconductor stack 55 may include a buffer layer 52 provided therebetween.

The LED 50′ may further include a current distribution layer 57′ disposed on the second conductive semiconductor layer 55c. An insulating layer 54′ may be disposed on the current distribution layer 57′, underneath at least of a portion of a second electrode 59.

Similarly to the above-described exemplary embodiments, a first electrode 58 may include a first electrode pad 58a and a first electrode finger 58b extending respectively therefrom. The semiconductor stack 55 may include a plurality of trenches Ta for the first electrode finger 58b. Similar to the first trenches Ta of FIG. 8, the trenches Ta may pass through the second conductive semiconductor layer 55c and the active layer 55b to allow portions of the first conductive semiconductor layer 55a to be exposed, and may be arranged in a longitudinal direction of the first electrode finger 58b.

The insulating layer 54′ may be provided on a lower portion of the first electrode 58 and internal side walls of the trenches Ta. The insulating layer 54′ may have open portions e by which bottom surfaces of the trenches Ta are exposed, and the first electrode finger 58b and the first conductive semiconductor layer 55a may be connected to each other through the open portions e as indicated by a reference symbol C.

A second electrode 59′ may include a second electrode pad 59a′ and a second electrode finger 59b′ extending respectively therefrom. As illustrated in FIG. 12, the second electrode 59′ employed in an exemplary embodiment may be disposed on the insulating layer 54′. The insulating layer 54′ disposed below the second electrode pad 59a′ may function as a current blocking layer (CBL). The insulating layer 54′ may include a plurality of openings O formed in a direction in which the second electrode finger 59b′ is arranged. In the openings O, the second electrode finger 59b′ may be connected to the current distribution layer 57′ exposed by the openings O. Adjustment of intervals between each of the openings O and areas thereof may allow areas of contact portions between the second electrode finger 59b′ and the current distribution layer 57′ and intervals between each of the areas to be controlled. As such, use of the openings O of the insulating layer 54′ may allow current distribution within the LED 50′ to be effectively controlled, similar to the trenches Ta.

The LED according to the above-described exemplary embodiments may be employed as a light source in various types of applications.

FIG. 13 is a cross-sectional view of an LED package 400 employing the LED described above with reference to various exemplary embodiments.

The LED package 400 illustrated in FIG. 13 may include the LED 402, a mounting substrate 410, and an encapsulant 408. The LED 402 may be disposed on the mounting substrate 410 to be electrically connected to the mounting substrate 410 through a wire W. The mounting substrate 410 may include a substrate body 411, an upper electrode 413, a lower electrode 414, and a through electrode 412 connecting the upper electrode 413 to the lower electrode 414. The mounting substrate 410 may be provided as a substrate such as a printed circuit board (PCB), a metal core printed circuit board (MCPCB), a metal printed circuit board (MPCB), or a flexible printed circuit board (FPCB), and a structure of the mounting substrate 410 may be applied in various forms.

The encapsulant 408 may have a dome-shaped lens structure having an upper convex surface, and may adjust an orientation angle of light emitted by introducing a different structure.

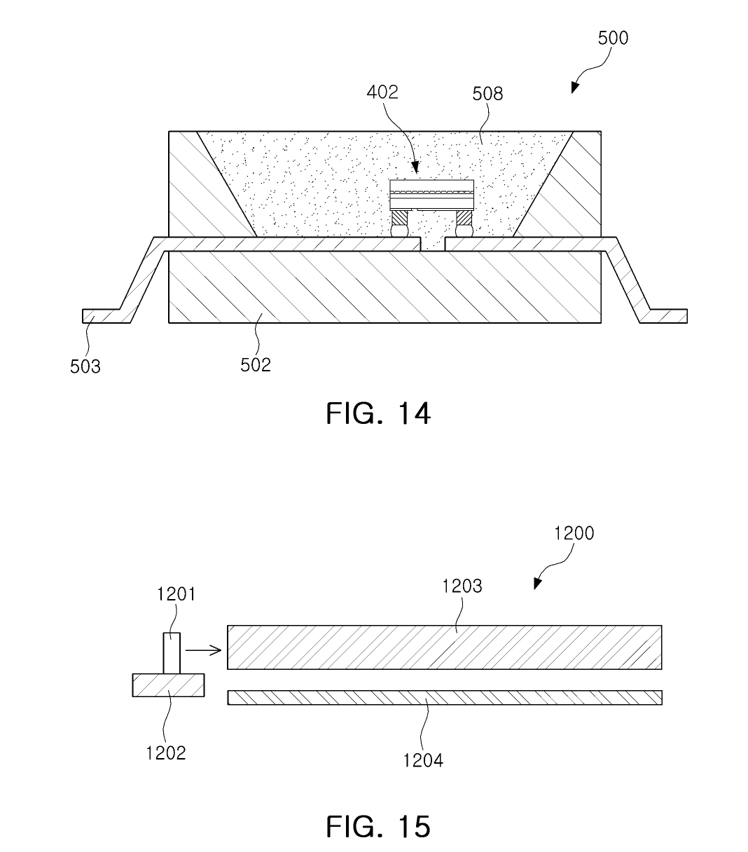

FIG. 14 is a cross-sectional view of an LED package 500 employing the LED described above with reference to various exemplary embodiments.

The LED package 500 illustrated in FIG. 14 may include the LED 402, a package body 502, and a pair of lead frames 503.

The LED 402 may be disposed on the lead frame 503, and respective electrode pads of the LED 402 may be electrically connected to the lead frame 503 in a flip-chip bonding manner. For example, the LED 402 may be disposed on a different portion besides that of the lead frame 503, such as on the package body 502. The package body 502 may have a groove portion having a cup shape so that light reflection efficiency may be increased, and an encapsulant 508 including a light transmitting material may be formed in the groove portion to encapsulate the LED 402.

The encapsulants 408 and 508 may contain a wavelength converting material, such as a phosphor and/or a quantum dot, for example.

A phosphor may have the following formulae and colors: yellow and green Y₃Al₅O₁₂:Ce, yellow and green Tb₃Al₅O₁₂:Ce, and yellow and green Lu₃Al₅O₁₂:Ce (oxide-based); yellow and green (Ba,Sr)₂SiO₄:Eu and yellow and orange (Ba,Sr)3SiO5:Ce (silicate-based); green β-SiAlON:Eu, yellow La₃Si₆N₁₁:Ce, orange α-SiAlON:Eu, red CaAlSiN₃:Eu, red Sr₂Si₅N₈:Eu, red SrSiAl₄N₇:Eu, and red SrLiAl₃N₄:Eu (nitride-based), Ln₄₋ₓ(Eu_{z}M_{1-z})ₓSi_{12-y}Al_{y}O_{3+x+y}N_{18-x-y} (0.5≦x≦3, 0<z<0.3, 0≦y≦4)—Formula (1), in which Ln may be at least one kind of element selected from the group consisting of group Ma elements and rare earth elements, and M may be at least one type of element selected from the group consisting of Ca, Ba, Sr and Mg; and KSF-based red K₂SiF₆:Mn⁴⁺, KSF-based red K₂TiF₆:Mn⁴⁺, KSF-based red NaYF₄:Mn⁴⁺, and KSF-based red NaGdF₄:Mn⁴⁺ (fluoride-based).

In addition, a quantum dot (QD) may be used to replace a phosphor or to be mixed with a phosphor as a wavelength converting material. The QD may implement various colors according to sizes thereof, and for instance, when used as a phosphor substitute, the QD may be employed as a red or green phosphor. In a case of using a QD, a narrow full width at half maximum (for example, about 35 nm) may be implemented.

The wavelength converting material may be implemented in the form contained in an encapsulant. Alternately, the wavelength converting material may be manufactured in the form of a film, and may be attached to a surface of an optical structure, such as an LED or a light guide plate. In this case, the wavelength converting material may be readily applied to a desired portion of a structure having a uniform thickness.

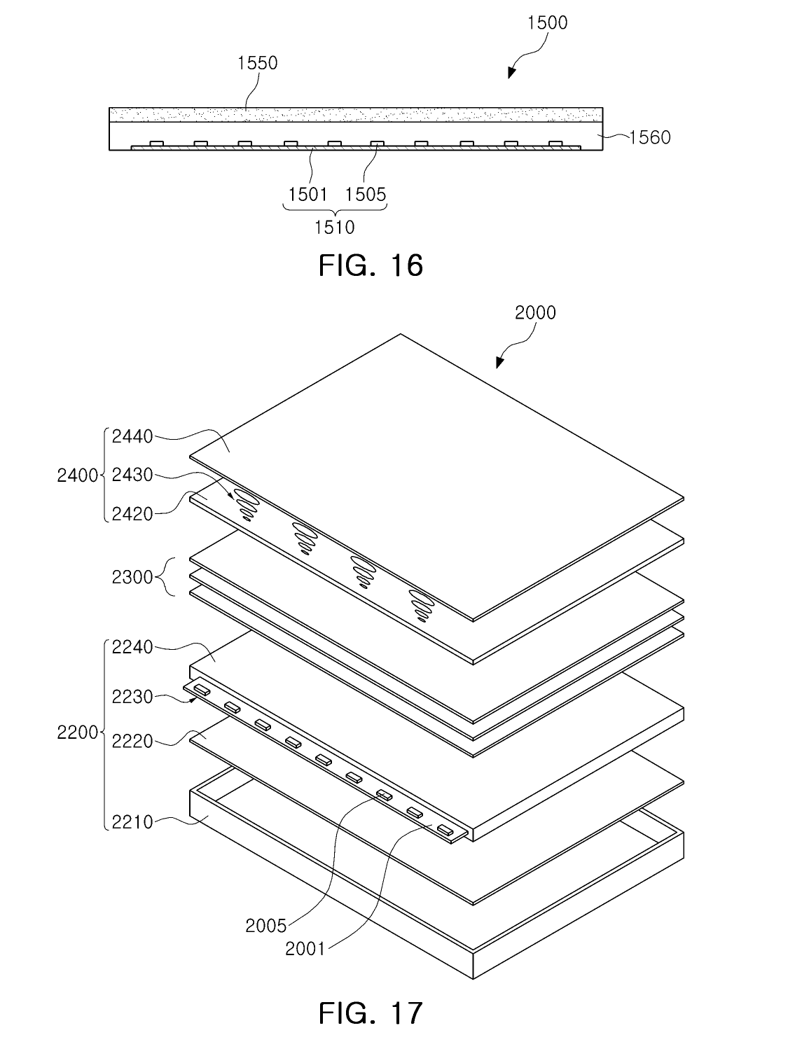

The wavelength converting material may be used in various types of light source devices, such as a backlight unit, a display device, and a lighting device. FIGS. 15 and 16 are cross-sectional views of backlight units according to exemplary embodiments, respectively, and FIG. 17 is an exploded perspective view of a display device according to an exemplary embodiment.

Referring to FIG. 15, a backlight unit 1200 may include a light guide plate 1203, and a circuit board 1202 disposed at a surface of the light guide plate 1203 and having a plurality of light sources 1201 mounted thereon. A reflective layer 1204 may be disposed below the light guide plate 1203 of the backlight unit 1200.

The light sources 1201 may radiate light to a surface of the light guide plate 1203, and the light may be incident on an inside of the light guide plate 1203 to be reflected above the light guide plate 1203. The backlight device according to an exemplary embodiment may also be referred to as an “edge-type backlight unit.” The light sources 1201 may include the above-described LED or the LED package including the same, together with a wavelength converting material. For example, the light sources 1201 may be the LED packages 400 and/or 500.

Referring to FIG. 16, a backlight unit 1500 as a direct-type backlight unit may include a wavelength converter 1550, a light source module 1510 arranged below the wavelength converter 1550, and a bottom case 1560 accommodating a light source module 1510. The light source module 1510 may also include a PCB 1501 and a plurality of light sources 1505 disposed on an upper surface of the PCB 1501. The light sources 1505 may be the above-described LED or the LED package including the same. The light sources 1505 are not used with a wavelength converting material.

The wavelength converter 1550 may be properly selected to emit white light according to wavelengths of the light sources 1505. The wavelength converter 1550 may be manufactured as a separate film, or may be integrated with another optical element, such as a separate light diffusion plate. As such, in an exemplary embodiment, the wavelength converter 1550 may be disposed to be spaced apart from the light sources 1505, thereby reducing deterioration of reliability of the wavelength converter 1550 caused by heat emitted by the light sources 1505.

FIG. 17 is a schematic exploded perspective view of a display device according to an exemplary embodiment.

Referring to FIG. 17, a display device 2000 may include a backlight unit 2200, an optical sheet or sheets 2300, and an image display panel 2400 such as a liquid crystal display (LCD) panel.

The backlight unit 2200 may include a bottom case 2210, a reflector 2220, a light guide plate 2240, and a light source module 2230 provided on at least one surface of the light guide plate 2240. The light source module 2230 may include a PCB 2001 and light sources 2005. The light sources 2005 may be the above-described LEDs or the LED package including the same. The light sources 2005 employed in an exemplary embodiment may be a side view-type light emitting device disposed on a surface adjacent to a light emitting surface. According to an exemplary embodiment, the backlight unit 2200 may include any one of the backlight units 1200 and 1500 respectively illustrated in FIGS. 15 and 16.

The optical sheet 2300 may be disposed between the light guide plate 2240 and the image display panel 2400, and may include various kinds of sheets, such as a diffusion sheet, a prism sheet, and a protection sheet.

The image display panel 2400 may display an image using light emitted through the optical sheets 2300. The image display panel 2400 may include an array substrate 2420, a liquid crystal layer 2430, and a color filter substrate 2440. The array substrate 2420 may include pixel electrodes disposed in a matrix, thin film transistors applying a driving voltage to the pixel electrodes, and signal lines operating the thin film transistors. The color filter substrate 2440 may include a transparent substrate, a color filter, and a common electrode. The color filter may include filters selectively passing light having a certain wavelength out of white light emitted by the backlight unit 2200. The liquid crystal layer 2430 may be re-arranged by an electrical field generated between the pixel electrodes and the common electrode to adjust light transmittance. Light with adjusted light transmittance may be projected to display an image by passing through the color filter of the color filter substrate 2440. The image display panel 2400 may further include a driving circuit unit or the like processing an image signal.

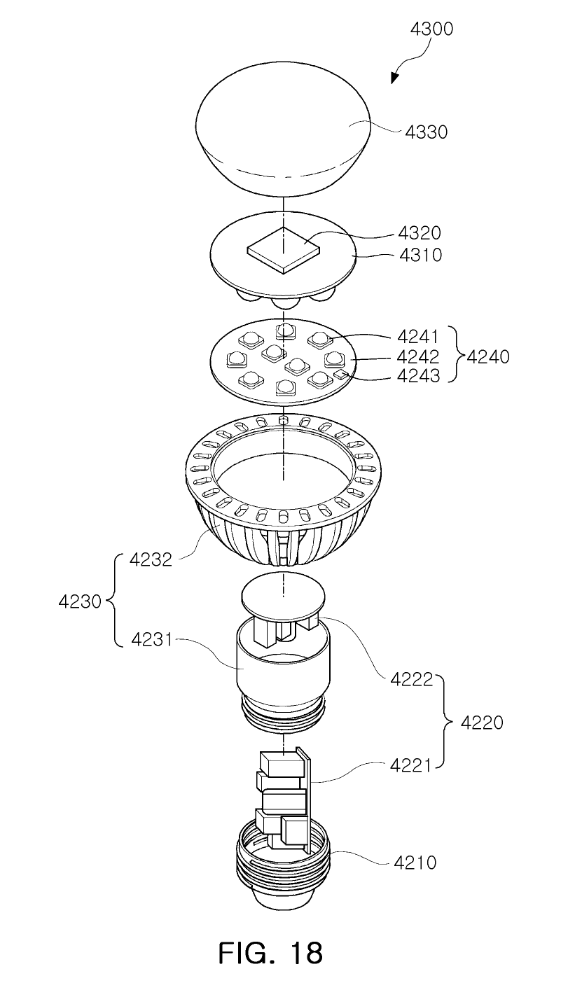

FIG. 18 is an exploded perspective view of an LED lamp employing an LED according to an exemplary embodiment.

Referring to FIG. 18, a lighting device 4300 may include a socket 4210, a power supply 4220, a heat sink 4230, and a light source module 4240. According to an exemplary embodiment, the light source module 4240 may include an LED array, and the power supply 4220 may include an LED driver.

The socket 4210 may be configured to replace that of a related art lighting device. Power supplied to the lighting device 4200 may be applied through the socket 4210. As illustrated in FIG. 18, the power supply 4220 may be separately attached with a first power supply 4221 and a second power supply 4222. The heat sink 4230 may include an internal heat sink 4231 and an external heat sink 4232. The internal heat sink 4231 may be directly connected to the light source module 4240 and/or the power supply 4220. This may allow heat to be transferred to the external heat sink 4232.

The light source module 4240 may receive power from the power supply 4220 to emit light to an optical unit 4330. The light source module 4240 may include light sources 4241, a circuit board 4242, and a controller 4243, and the controller 4243 may store driving information of the light sources 4241. The light sources 4241 may be the above-described LEDs or the LED package including the same.

A reflector 4310 may be disposed above the light source module 4240, and may reduce glare by evenly spreading light emitted by the light sources 4241 to a side and a rear of the reflector 4310. In addition, a communications module 4320 may be disposed on the reflector 4310, and may perform home network communications. For example, the communications module 4320 may be a wireless communications module using Zigbee®, Wi-Fi, or light fidelity (Li-Fi), and may control on/off functions and brightness of a lighting device installed in and around a home through a smartphone or a wireless controller. Further, use of a Li-Fi communications module using a visible light wavelength of a lighting device installed in and around residential, commercial, or industrial spaces may control electronics such as a TV, a refrigerator, an air-conditioner, a door lock, or may control a vehicle. The reflector 4310 and the communications module 4320 may be covered with the optical unit 4330.

As set forth above, according to an exemplary embodiment, an effective light emission region may be reduced by forming a plurality of trenches by not etching all regions in which a first electrode (for example, an n-type electrode) is to be formed. An additional current distribution effect may be expected to be provided in a region in which an electrical current is concentrated by adjusting intervals between each of such trenches. Disposing an insulating layer below the first electrode may allow a metal forming the first electrode and the insulating layer to be provided as an ODR structure, thereby substantially improving light extraction efficiency.

The intervals between each of the trenches may be controlled to provide a light emission region therebetween to have a micro size, and light efficiency may be greatly increased with effects of a micro LED.

According to exemplary embodiments, an n-type electrode may be disposed over trench regions in order to improve current distribution and light extraction efficiency while minimizing a loss of an active region caused by the n-type electrode (finger electrode). As a result, an active layer removal region is reduced, thereby increasing a light emission region.

Additionally, a current concentration effect may be reduced by controlling the arrangement interval of trenches and the area of contact between the n-type electrode and a first conductive semiconductor layer in each of the trenches.

A region between the trenches may function as a micro LED, which is provides an improvement in light efficiency.

The foregoing exemplary embodiments and advantages are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

1. A light emitting device (LED) comprising:
a semiconductor stack including a first conductive semiconductor layer, a second conductive semiconductor layer, an active layer disposed between the first and second conductive semiconductor layers, and trenches formed passing through the second conductive semiconductor layer and the active layer to expose portions of the first conductive semiconductor layer disposed underneath the active layer;
a first electrode finger disposed along the trenches and electrically connected to the portions of the first conductive semiconductor layer exposed within the trenches;
an insulating layer on which the first electrode finger is positioned and which is disposed on the second conductive semiconductor layer and internal side walls of the trenches; and
a second electrode finger electrically connected to the second conductive semiconductor layer.

2. The LED of claim 1, further comprising a current distribution layer disposed on the second conductive semiconductor layer,
wherein the second electrode finger is disposed on the current distribution layer.

3. The LED of claim 2, wherein the current distribution layer is disposed on an upper surface of the second conductive semiconductor layer excluding a portion, of the upper surface of the second conductive semiconductor, in which the first electrode finger is disposed.

4. The LED of claim 2, wherein the current distribution layer comprises a transparent electrode layer.

5. The LED of claim 4, wherein the current distribution layer includes at least one from indium tin oxide (ITO), zinc-doped ITO (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In₄Sn₃O₁₂, and zinc magnesium oxide (Zn₍₁₋ₓ₎MgₓO, 0≦x≦1).

6. The LED of claim 1, wherein the first electrode finger and portions of the insulating layer disposed below the first electrode finger form an omni-directional reflector (ODR).

7. The LED of claim 1, wherein at least a portion of the insulating layer comprises a distributed Bragg reflector (DBR) multilayer film.

8. The LED of claim 1, wherein the trenches are disposed to be spaced apart from one another, and
a distance between at least two of neighboring trenches is different from a distance between other two neighboring trenches.

9. The LED of claim 1, wherein a contact area between the first electrode finger and the first conductive semiconductor layer in at least one trench is different from that in another trench, of the trenches.

10. The LED of claim 1, further comprising a first electrode pad and a second electrode pad respectively connected to the first electrode finger and the second electrode finger.

11. The LED of claim 10, wherein the first electrode pad is disposed on a portion of the insulating layer positioned on the second conductive semiconductor layer, and
the second electrode pad is disposed on the second conductive semiconductor layer.

12. The LED of claim 10, wherein the trenches include a first trench, which is disposed proximate the first electrode pad at a first distance, and other trenches which are disposed one after another, after the first trench, in a direction away from the first electrode pad, and are spaced apart from the first trench and from one another at second distances, and
at least one of the second distances is greater than the first distance between the first trench and the first electrode pad.

13. The LED of claim 10, wherein a contact area between the first electrode finger and the first conductive semiconductor layer in the trenches is reduced as the trenches are positioned farther away from the first electrode pad.

14. The LED of claim 10, wherein the trenches include a first trench, which is disposed proximate the first electrode pad at a first distance, and other trenches which are disposed one after another, after the first trench, in a direction away from the first electrode pad, and are spaced apart from the first trench and from one another at second distances, and
at least one of the second distances is smaller than the first distance between the first trench and the first electrode pad.

15. The LED of claim 10, wherein a contact area between the first electrode finger and the first conductive semiconductor layer in the trenches is increased as the trenches are positioned farther away from the first electrode pad.

16. A light emitting device (LED) comprising:
a semiconductor stack including a first conductive semiconductor layer, a second conductive semiconductor layer, an active layer disposed between the first and second conductive semiconductor layers, first trenches, and a second trench, the first trenches and the second trench passing through the second conductive semiconductor layer and the active layer to expose portions of the first conductive semiconductor layer;
a first electrode finger disposed along the first trenches and connected to the portions of the first conductive semiconductor layer that are exposed within the first trenches;
an insulating layer disposed on the second conductive semiconductor layer and internal side walls of the first trenches, and on an internal surface of the second trench; and
a second electrode finger disposed on the insulating layer within the second trench and electrically connected to the second conductive semiconductor layer.

17. The LED of claim 16, further comprising a current distribution layer disposed on the second conductive semiconductor layer and electrically connected to the second electrode finger,
wherein the current distribution layer extends into the second trench along an upper surface of the insulating layer, and
the second electrode finger is disposed on a portion of the current distribution layer positioned within the second trench.

18. The LED of claim 16, wherein bottom surfaces of the first trenches and a bottom surface of the second trench are disposed at substantially the same depth.

19. The LED of claim 16, wherein the second trench is included into a plurality of second trenches, and
the second electrode finger is disposed along the plurality of second trenches.

20. The LED of claim 16, further comprising a first electrode pad and a second electrode pad respectively connected to the first electrode finger and the second electrode finger,
wherein the insulating layer has a portion extending between the second electrode pad and the second conductive semiconductor layer.

21-25. (canceled)
